(19) United States
(12) Patent Application Publication
(10) Pub. No.: US 2012/0153349 A1
(43) Pub. Date: Jun. 21, 2012

(54) SEMICONDUCTOR DEVICE AND METHOD OF MANUFACTURING THE SAME

(75) Inventor: Kenji SUZUKI, Tokyo (JP)

(73) Assignee: MITSUBISHI ELECTRIC CORPORATION, Tokyo (JP)

(21) Appl. No.: 13/206,808

(22) Filed: Aug. 10, 2011

(30) Foreign Application Priority Data
Dec. 20, 2010 (JP) 2010-282655

(51) Int. Cl. H01L 27/06; H01L 21/331

(52) U.S. Cl. 257/140; 438/135; 257/E27.011; 257/E21.382

(57) ABSTRACT

Provided is a semiconductor device including: a first gate wiring line connected to a gate electrode through an upper surface of the gate electrode that is not covered with a first interlayer insulating film; a second interlayer insulating film formed on the first interlayer insulating film so as to cover a region other than part of an upper surface of the first gate wiring line; and a second gate wiring line connected to the first gate wiring line through the upper surface of the first gate wiring line that is not covered with the second interlayer insulating film, the second gate wiring line having a width larger than a width of the first gate wiring line in plan view.

### BACKGROUND OF THE INVENTION

1. Field of the Invention

The present invention relates to a semiconductor device and a method of manufacturing the same, and more particularly, to the structure of an electrode and a method of manufacturing the same for improving the performance and quality of a power semiconductor device such as an IGBT.

2. Description of the Background Art

Nowadays, semiconductor devices such as an IGBT are used in various purposes, whose performance as well as quality are desired to be further improved.

While the performance and quality of an IGBT have been improved mainly by the review of the cell structure and the optimization of a wafer thickness, such improvements are approaching the limits that can be obtained only by those means. Therefore, it is important to increase the ratio of the area of an emitter region per unit area (that is, increase an effective area to reduce a current density) for improving the performance and quality.

For example, in a case of an IGBT with a temperature sensing diode as shown in Japanese Patent Application Laid-Open No. 2009-283717, an emitter electrode cannot be formed in a region directly below an electrode pad and a wiring line of a temperature sensing diode, and thus such a region becomes ineffective. Therefore, it is necessary to newly create an effective area.

It is effective to reduce an electrode pad in size and shorten a wiring line length for increasing an effective area. However, the electrode pad requires an area (for example, wire diameter) at least for connection (for example, Al wire) with the outside, which imposes limitations on the area reduction.

Further, a large gate resistance of a gate electrode included in a semiconductor device causes variations in chip operation, resulting in an imbalanced operation in which current is concentrated on partial chips.

### SUMMARY OF THE INVENTION

An object of the present invention is to provide a semiconductor device capable of preventing, for example, an imbalanced operation while increasing an effective area of a cell, and a method of manufacturing the same.

A semiconductor device according to the present invention includes: a gate electrode selectively formed on an insulating film and connected to individual gate electrodes of a plurality of cells; a first interlayer insulating film formed on the insulating film so as to cover a region other than part of an upper surface of the gate electrode; a first gate wiring line connected to the gate electrode through the upper surface that is not covered with the first interlayer insulating film; a second interlayer insulating film formed on the first interlayer insulating film so as to cover a region other than part of an upper surface of the first gate wiring line; and a second gate wiring line connected to the first gate wiring line through the upper surface that is not covered with the second interlayer insulating film. The width of the second gate wiring line is larger than the width of the first gate wiring line in plan view.

According to the semiconductor device of the present invention, it is possible to reduce a parasitic gate resistance in an IGBT chip and prevent an imbalanced operation.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a view showing a manufacturing step after an electrode pad according to a first preferred embodiment of the present invention is formed;

FIG. 2 is a view showing an upper main surface of a semiconductor device according to the first preferred embodiment of the present invention;

FIG. 3 is a cross-sectional view of a temperature sensing diode according to the first preferred embodiment of the present invention;

FIG. 4 is a cross-sectional view of a second gate wiring line formed directly above a first gate wiring line according to the first preferred embodiment of the present invention;

FIG. 5 is a view showing an upper main surface of a semiconductor device according to a second preferred embodiment of the present invention;

FIG. 6 is a cross-sectional view of a second emitter electrode formed directly above a first gate wiring line according to the second preferred embodiment of the present invention;

FIG. 7 is a cross-sectional view of a termination region according to a third preferred embodiment of the present invention;

FIGS. 8 and 9 are views showing the steps of manufacturing the termination region according to the third preferred embodiment of the present invention;

FIG. 10 is a cross-sectional view of the termination region according to the third preferred embodiment of the present invention;

FIGS. 11 and 12 are views showing the steps of manufacturing the termination region according to the third preferred embodiment of the present invention;

FIG. 13 is a view showing an upper main surface of a semiconductor device according to a fourth preferred embodiment of the present invention;

FIG. 14 is a cross-sectional view of a third emitter electrode according to the fourth preferred embodiment of the present invention;

FIG. 15 is a view showing an upper main surface of an IGBT with a temperature sensing diode according to the underlying technology of the present invention;

FIG. 16 is a cross-sectional view of the temperature sensing diode of the IGBT with the temperature sensing diode according to the underlying technology;

FIG. 17 is a cross-sectional view of a first gate wiring line of the IGBT according to the underlying technology; and

FIGS. 18 and 19 are cross-sectional views of a termination region of the IGBT according to the underlying technology.

### DESCRIPTION OF THE PREFERRED EMBODIMENTS

### A. First Preferred Embodiment

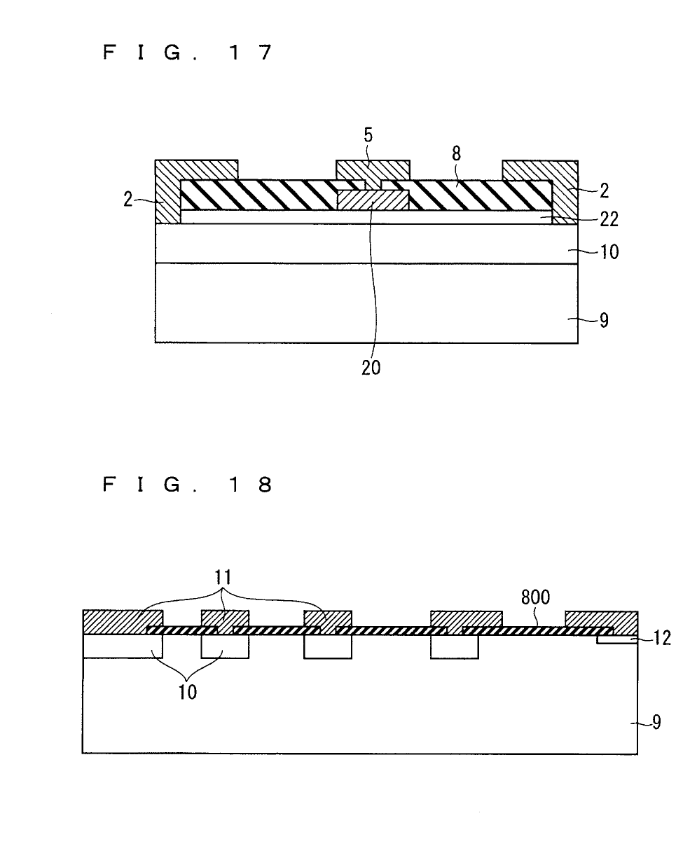

FIG. 15 shows an upper main surface of an IGBT chip according to the underlying technology of the present invention.

In plan view, the cell region in which a first emitter electrode 2 is formed is surrounded by a first gate wiring line 5, and the region outside the cell region is a termination region 1. The cell region refers to a region in which a plurality of unit elements (cells) such as IGBTs are arranged.

In the region in which the first emitter electrode 2 is formed, a temperature sensing diode 3 is disposed in the center part thereof, and wiring lines 4 for the temperature sensing diode 3, which are connected to the temperature sensing diode 3, and further electrode pads 6 for the temperature sensing diode 3, which are connected to the wiring lines 4, are disposed.

Further, a plurality of first gate wiring lines 5 connected to a first gate electrode pad 7 are arranged also in the region in which the first emitter electrode 2 is formed.

The first gate electrode pad 7 and the first gate wiring line 5 use the same electrode and are formed by selective etching.

The first gate electrode pad 7 is formed as an electrode pad that transmits the gate voltage from the outside, for example, as an electrode pad for wire bonding. The first gate wiring lines 5 are distributed from the first gate electrode pad 7 to be arranged, and apply the gate voltage to the IGBT cells connected in parallel.

The first emitter electrode 2 is a region for allowing an emitter current (main current) to flow, and the IGBT cells connected in parallel are formed below the first emitter electrode 2.

The temperature sensing diode 3 senses the heating temperature of the element by voltage drop of the diode, and has a function of turning off the IGBT to protect the chip from thermal breakdown when a maximum rated temperature is exceeded.

Further, the termination region 1 is configured to keep the voltage applied across the collector and the emitter when the gate voltage is OFF.

FIG. 16 is a cross-sectional view taken along A-A′ of FIG. 15. As shown in FIG. 16, an interlayer insulating film 801 is formed on an n− substrate 9, and further, the wiring lines 4 for the temperature sensing diode 3 are formed on the interlayer insulating film 801.

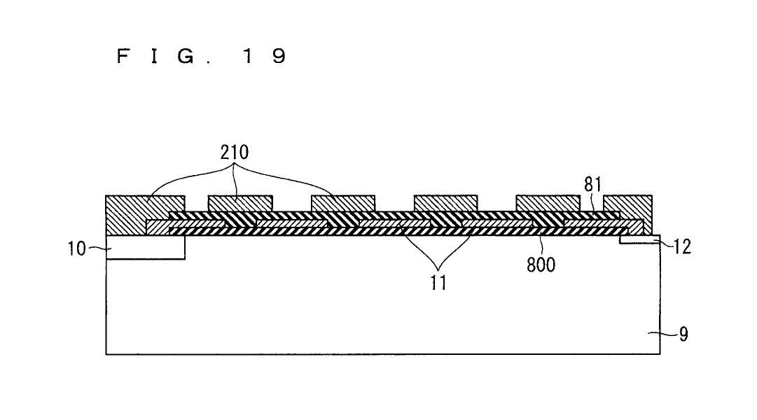

FIG. 17 is a cross-sectional view taken along G-G′ of FIG. 15. As shown in FIG. 17, a p well layer 10 is formed on the n− substrate 9, and an oxide film 22 is selectively formed on the p well layer 10.

Formed on the oxide film 22 is a gate electrode 20, and an interlayer insulating film 8 is formed so as to sandwich the gate electrode 20. In this case, the interlayer insulating film 8 is formed so as to cover the gate electrode 20 except for part of the upper surface of the gate electrode 20. The gate electrodes 20 are formed in a layout similar to that of the gate wiring lines 5 shown in FIG. 15, that is, are formed to extend in the vertical direction of FIG. 15 and n− substrate 9 to surround the cell region.

Further, the first gate wiring line 5 is connected to the gate electrode 20 through the upper surface of the gate electrode 20, which is not covered with the interlayer insulating film 8.

Further, the first emitter electrode 2 is formed on the p well layer 10 so as to sandwich the oxide film 22 and the interlayer insulating film 8.

FIG. 18 is a cross-sectional view taken along B-B′ of FIG. 15, which shows the guard ring structure in which a plurality of floating p well layers 10 are disposed in a ring shape. As shown in FIG. 18, the p well layers 10 are formed in the surface of the n− substrate 9, while the plurality of ring-shaped p well layers 10, which surround the region in which the first emitter electrode 2 is formed in plan view, are formed in the termination region 1. Further, a channel stopper 12 is formed on the outermost boundary.

Formed on the respective p well layers 10 and the channel stopper 12 are first field plate electrodes 11 connected to the upper surfaces thereof that are not covered with an interlayer insulating film 800. The first field plate electrode 11 can be made of, for example, aluminum.

FIG. 19 shows another aspect of the cross section taken along B-B′ of FIG. 15, which shows the field plate structure using capacitive coupling. As shown in FIG. 19, the p well layer 10 is formed in the surface of the n− substrate 9, and the channel stopper 12 is formed on the outermost boundary.

The first field plate electrodes 11 connected to the upper surfaces of the p well layer 10 and the channel stopper 12, which are not covered with the interlayer insulating film 800, are formed on the p well layer 10 and the channel stopper 12. Further, a plurality of first field plate electrodes 11 are also formed in a ring shape, through the interlayer insulating film 800, in the region between the p well layer 10 and the channel stopper 12. The first field plate electrode 11 can be made of, for example, polysilicon.

Further, third field plate electrodes 210 are formed on the first field plate electrodes 11 through an interlayer insulating film 81 (which are connected to part of the interlayer insulating film 81).

In a semiconductor device as described above, an emitter electrode cannot be formed in the region directly below the electrode pad and wiring line for the temperature sensing diode as shown in FIG. 16, and such a region becomes ineffective. This requires to newly increase the effective area.

Note that in the region other than the region immediately below the electrode pad and wiring line for the temperature sensing diode, individual gate electrodes (not shown) are formed in a stripe shape so as to extend in a horizontal direction of FIG. 15, and are arranged in a plurality of lines. The individual gate electrode is connected to the gate electrode 20 at the position at which the individual gate intersects with the gate electrode 20.

In order to increase an effective area, it is effective to reduce the electrode pad in size and shorten the wiring line length. However, the electrode pad needs the area (for example, wire diameter) for connection at least with the outside (for example, Al wire), which imposes limitations on the reduction of the area.

In general, the temperature sensing diode is desirably disposed in the vicinity of the center of the chip that produces the highest heat among the semiconductor chips, leading to a problem that the detection sensitivity decreases in a case where the temperature sensing diode is disposed in the end of the semiconductor chip.

Unfortunately, a large gate resistance of the gate electrode included in the semiconductor device causes variations in chip operation, leading to an imbalanced operation in which current is concentrated on partial chips.

In recent years, the transfer mold technique is applied to a number of products, where unfortunately, the wiring line formed on the semiconductor slides by the stress from a molding resin due to a difference in thermal expansion coefficient between a molding resin and a semiconductor chip. The stress relaxation in which the film thickness of the electrode is made smaller to reduce a step is taken as an example of the countermeasures against this. However, as described above, the width (cross-sectional area) of the gate wiring line is limited, and the cell part may be damaged when the gate wiring line is connected to the electrode by wire bonding, which leads to a threshold. As another countermeasure, the wiring line is protected by polyimide coating, which leads to a cost increase.

In the preferred embodiments below, semiconductor devices capable of solving the above-mentioned problems are described.

<A-1. Configuration>

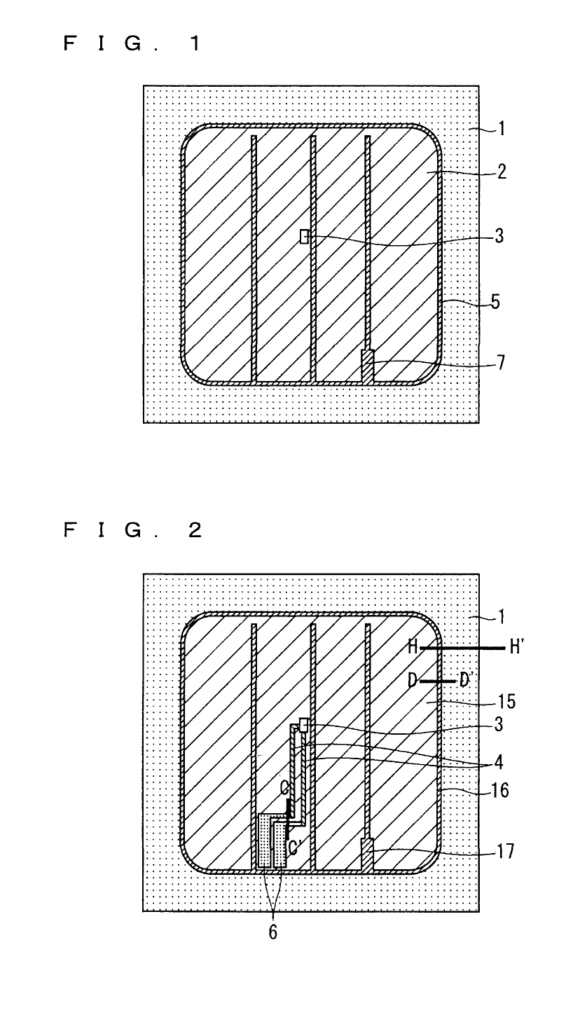

FIG. 1 is a view showing a manufacturing step after an electrode pad according to a first preferred embodiment is formed. The region in which a first emitter electrode 2 is formed, which is the upper main surface corresponding to the lower surface of FIG. 2 described below, is surrounded by a first gate wiring line 5 in plan view, and the region surrounded by the first gate wiring line 5 is referred to as the cell region. The region outside the cell region is a termination region 1.

A temperature sensing diode 3 is disposed in the center part of the cell region in which the first emitter electrode 2 is formed.

Further, a plurality of first gate wiring lines 5 connected to the first gate electrode pad 7 are arranged also in the cell region.

FIG. 2 shows the upper main surface of an IGBT as a semiconductor device according to the first preferred embodiment of the present invention, which shows the state in which the manufacturing step proceeds further from the state of FIG. 1.

In plan view, the cell region in which a second emitter electrode 15 corresponding to the upper layer of the first emitter electrode 2 is formed is surrounded by a second gate wiring line 16, and the region outside the cell region is the termination region 1. The second gate wiring line 16 also corresponds to the upper layer of the first gate wiring line 5. The formation of the second emitter electrode 15 strengthens the fixation of the potential of an emitter in an IGBT chip, which prevents an imbalanced operation.

In the cell region in which the second emitter electrode 15 is formed, the temperature sensing diode 3 is disposed in the center part thereof, and wiring lines 4 for the temperature sensing diode 3, which are connected to the temperature sensing diode 3, and further electrode pads 6 for the temperature sensing diode 3, which are connected to the wiring lines 4, are disposed.

Further, a plurality of second gate wiring lines 16 connected to a second gate electrode pad 17 are arranged in the cell region.

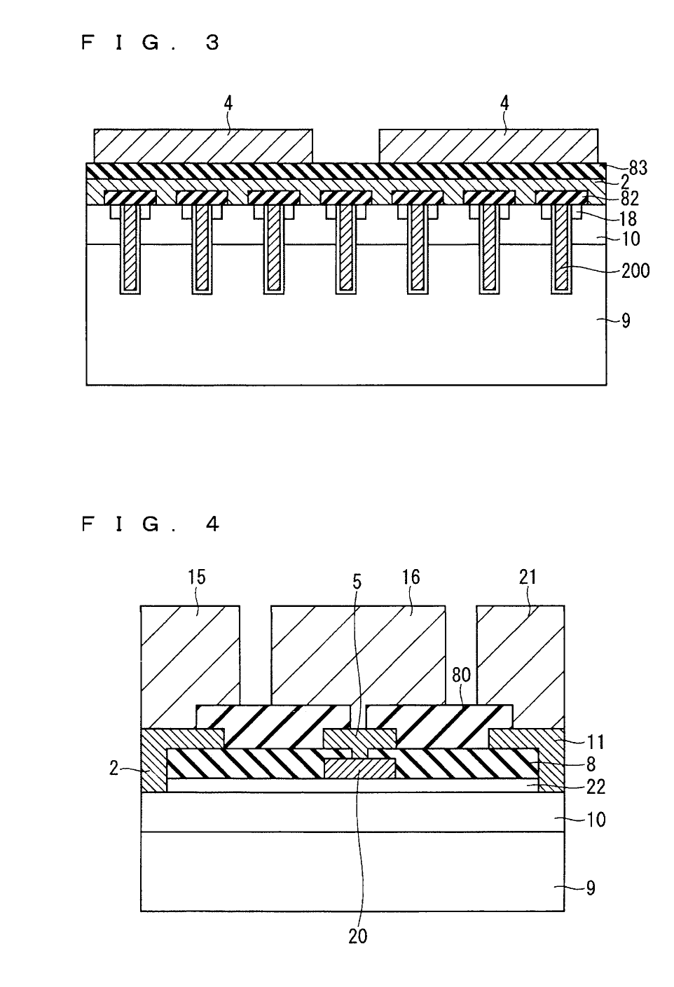

FIG. 3 is a cross-sectional view taken along C-C′ of FIG. 2. As shown in FIG. 3, a p well layer 10 (p base layer) is formed on an n− substrate 9, and individual gate electrodes 200 are formed so as to extend from the surface of the p well layer 10 (p base layer) to the inside of the n− substrate 9.

Note that the individual gate electrodes 200 (not shown) are formed in a strip shape so as to extend in the horizontal direction of FIG. 1 to be arranged in a plurality of lines in the region other than the region directly below the electrode pad 6 and wiring lines 4 for the temperature sensing diode 3. The individual gate electrode 200 is connected to a gate electrode 20 at a position at which the individual gate electrode 200 intersects with the gate electrode 20.

Further, formed on the surface of the p well layer 10 so as to sandwich the individual gate electrode 200 is an n+ emitter layer 18 as an emitter layer of each cell. Further, an interlayer insulating film 82 is formed as a fourth interlayer insulating film so as to cover the individual gate electrodes 200 on the surface of the p well layer 10.

Further, the first emitter electrode 2 is formed so as to cover the p well layer 10 including the interlayer insulating film 82. Formed selectively on the first emitter electrode 2 is an interlayer insulating film 83 as a fifth interlayer insulating film. A MOS transistor is formed below the first emitter electrode 2. Note that the first emitter electrode 2 is connected to the n+ emitter layer 18 in cross section (not shown).

The wiring lines 4 for the temperature sensing diode 3 are selectively disposed on the interlayer insulating film 83. Note that in the cross section in which the electrode pads 6 for the temperature sensing diode 3 are disposed on the interlayer insulating film 83, the electrode pads 6 are disposed in place of the wiring lines 4 for the temperature sensing diode 3.

In the case of the semiconductor device shown in FIG. 15, the effective area of the emitter electrode is reduced by the electrode pads 6 and the wiring lines 4. On the other hand, in the first preferred embodiment, a MOS transistor can also be disposed directly below the wiring line 4, which prevents a reduction in effective area.

In the first preferred embodiment, a MOS transistor can be formed below the electrode pad 6 and wiring line 4 for the temperature sensing diode 3 as described above, which produces an effect that an ineffective area can be minimized.

FIG. 4 is a cross-sectional view taken along D-D′ of FIG. 2. As shown in FIG. 4, the semiconductor device according to the present invention includes the p well layer 10 formed on the n− substrate 9, an oxide film 22 as an insulating film that is selectively formed on the surface of the p well layer 10, and the gate electrodes 20 selectively formed on the oxide film 22. The gate electrodes 20 are connected to the individual gate electrodes 200 of a plurality of cells. In addition, the gate electrodes 20 are formed in a layout similar to that of the gate wiring lines 5 shown in FIG. 1, that is, are formed to extend in the vertical direction of FIG. 1 and to surround the cell region.

Further, an interlayer insulating film 8 as a first interlayer insulating film is formed so as to cover the region other than part of the upper surface of the gate electrode 20. The interlayer insulating film 8 is formed on the oxide film 22 by selective etching such as deposition. The gate electrode 20 and the first gate wiring line 5 are connected to each other through part of the upper surface of the gate electrode 20, which is not covered with the interlayer insulating film 8. The first gate wiring line 5 is formed by depositing a conductive material such as aluminum by sputtering and deposition and then selectively etching the obtained film.

An interlayer insulating film 80 as a second interlayer insulating film is formed so as to cover the region other than part of the upper surface of the first gate wiring line 5. The interlayer insulating film 80 is formed on the interlayer insulating film 8. The first gate wiring line 5 and the second gate wiring line 16 are connected to each other through part of the upper surface of the first gate wiring line 5, which is not covered with the interlayer insulating film 80.

In this case, the width of the second gate wiring line 16 can be formed to be larger than the width of the first gate wiring line 5 in plan view.

Further, the first emitter electrode 2 and a first field plate electrode 11 can be formed through the interlayer insulating film 8 so as to sandwich the gate electrode 20 and the first gate wiring line 5 therebetween. The portion on the left of FIG. 4 in which the first emitter electrode 2 is formed corresponds to the cell region. Further, it is possible to form a second emitter electrode 15 and a second field plate electrode 21 on the first emitter electrode 2 and the first field plate electrode 11, respectively. In the case where the second emitter electrode 15 is formed, fixation of the potential of the emitter in the IGBT chip can be strengthened, which prevents an imbalanced operation. In the case where the second field plate electrode 21 is formed, the breakdown voltage can be stabilized.

In this case, the imbalanced operation refers to the operation in which chip operations vary and current is apt to be concentrated on partial chips in the case of a large gate resistance.

In the structure shown in FIG. 4, the width required for transmitting the potential of the gate is set by the first gate wiring line 5, and the width of the second gate wiring line 16 connected to the first gate wiring line 5 is formed to be larger than the width of the first gate wiring line 5, thereby setting a gate resistance. Therefore, the gate resistance can be set by the second gate wiring line 16, which reduces the parasitic gate resistance in the IGBT chip. As a result, the imbalanced operation can be prevented.

Note that the electrode pad 6 and wiring line 4 in the structure shown in FIG. 3 can be formed in the step of forming the second gate wiring line 16, second emitter electrode 15 and second field plate electrode 21 in the structure shown in FIG. 4.

Further, the individual gate electrode 200 and the gate electrode 20 can be formed in the same step. Similarly, the interlayer insulating film 8 and the interlayer insulating film 82, and the interlayer insulating film 80 and the interlayer insulating film 83 can be respectively formed in the same step.

<A-2. Effects>

According to the first preferred embodiment of the present invention, the semiconductor device includes: the first gate wiring line 5 connected to the gate electrode 20 through the upper surface of the gate electrode 20 that is not covered with the first interlayer insulating film 8; the second interlayer insulating film 80 formed on the first interlayer insulating film 8 so as to cover a region other than part of the upper surface of the first gate wiring line 5; and the second gate wiring line 16 connected to the first gate wiring line 5 through the upper surface of the first gate wiring line 5 that is not covered with the second interlayer insulating film 80, the second gate wiring line 16 having a width larger than the width of the first gate wiring line 5 in plan view. Accordingly, the parasitic gate resistance in the IGBT chip can be reduced, which prevents an imbalanced operation.

Further, according to the first preferred embodiment of the present invention, the semiconductor device further includes: the n+ emitter layers 18 as emitter layers for the respective cells, the n+ emitter layers 18 being formed adjacent to the individual gate electrodes 200; the fourth interlayer insulating film 82 formed so as to cover the individual gate electrodes 200; the first emitter electrode 2 formed on the fourth interlayer insulating film 82 so as to be connected to the n+ emitter layers 18; the fifth interlayer insulating film 83 formed on the first emitter electrode 2; and the electrode pad 6 for the temperature sensing diode 3 and/or the wiring line 4 for the temperature sensing diode 3, which are/is disposed on the fifth interlayer insulating film 83. Accordingly, an ineffective region can be prevented from being formed directly below the electrode pad 6 and wiring line 4 for the temperature sensing diode 3, which increases an effective area of the semiconductor device.

Further, according to the first preferred embodiment of the present invention, the semiconductor device further includes the second emitter electrode 15 formed on the first emitter electrode 2. Accordingly, the fixation of the potential of the emitter in the IGBT chip can be strengthened, and it is expected to prevent an imbalanced operation and oscillation and improve wire bondability.

Further, according to the first preferred embodiment of the present invention, in the semiconductor device, the electrode pad 6 for the temperature sensing diode 3 and the wiring line 4 for the temperature sensing diode 3 are formed in the step of forming the second gate wiring line 16 and the second emitter electrode 15. Accordingly, the number of steps is reduced, which improves working efficiency.

Further, according to the first preferred embodiment of the present invention, in the semiconductor device, the first gate wiring line 5, the first emitter electrode 2 and the first field plate electrode 11 are formed in the same step. Accordingly, the number of steps is reduced, which improves working efficiency.

Further, according to the first preferred embodiment of the present invention, in the semiconductor device, the second gate wiring line 16, the second emitter electrode 15 and the second field plate electrode 21 are formed in the same step. Accordingly, the number of steps is reduced, which improves working efficiency.

### B. Second Preferred Embodiment

<B-1. Configuration>

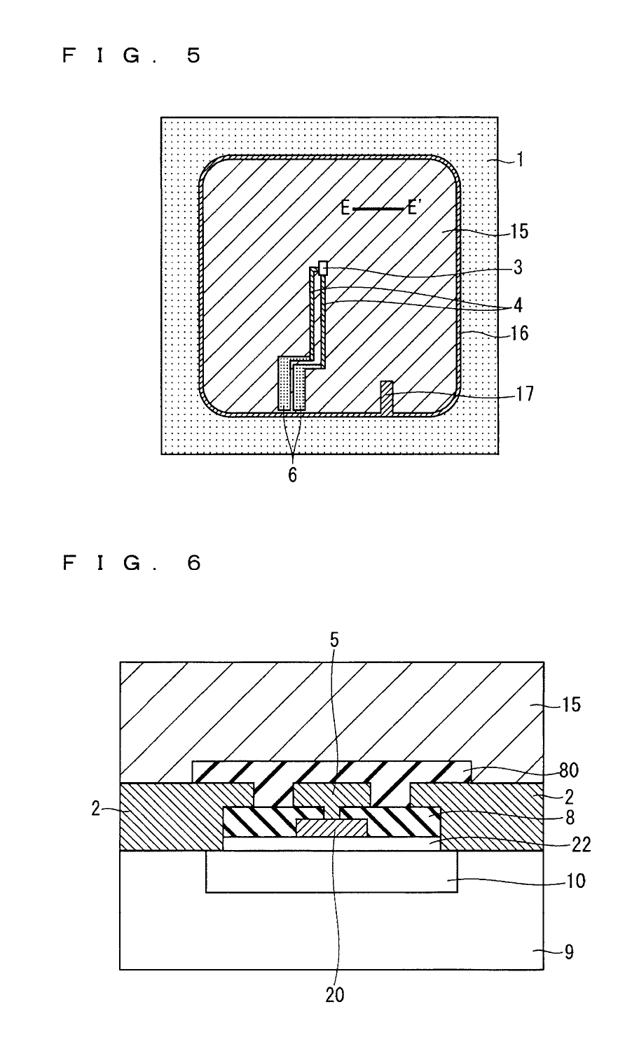

FIG. 5 shows the upper main surface of a semiconductor device according to a second preferred embodiment of the present invention. In plan view, the cell region in which the second emitter electrode 15 is formed is surrounded by the second gate wiring line 16, and the region outside the cell region is the termination region 1.

In the region in which the second emitter electrode 15 is formed, the temperature sensing diode 3 is disposed in the center part thereof, and the wiring lines 4 for the temperature sensing diode 3, which are connected to the temperature sensing diode 3, and further the electrode pads 6 for the temperature sensing diode 3, which are connected to the wiring lines 4, are disposed.

FIG. 6 is a cross-sectional view taken along E-E′ of FIG. 5. FIG. 6 is the cross-sectional view of the region which does not include the termination region 1, and thus the field plate electrode is not shown.

As shown, in FIG. 6, the interlayer insulating film 80 is formed to cover the first gate wiring line 5 at least partially (the first gate wiring line 5 is entirely covered in FIG. 6), and differently from the case shown in FIG. 4, the second emitter electrode 15 is formed to cover the region including the portion above the interlayer insulating film 80 in place of the second gate wiring line 16.

With the configuration described above, it is possible to prevent an imbalanced operation and oscillation and improve wire bondability by strengthening the fixation of the potential of the emitter in the IGBT chip.

<B-2. Effects>

According to the second preferred embodiment of the present invention, in the semiconductor device, the second interlayer insulating film 80 is formed so as to cover the first gate wiring line 5 at least partially, and the second emitter electrode 15 is formed at a position of the partially-covered first gate wiring line 5 so as to cover a region including the portion above the second interlayer insulating film 80 in place of the second gate wiring line 16. Accordingly, the fixation of the potential of the emitter in the IGBT chip can be strengthened, and it is expected to prevent an imbalanced operation and oscillation and improve wire bondability.

### C. Third Preferred Embodiment

<C-1. Configuration 1>

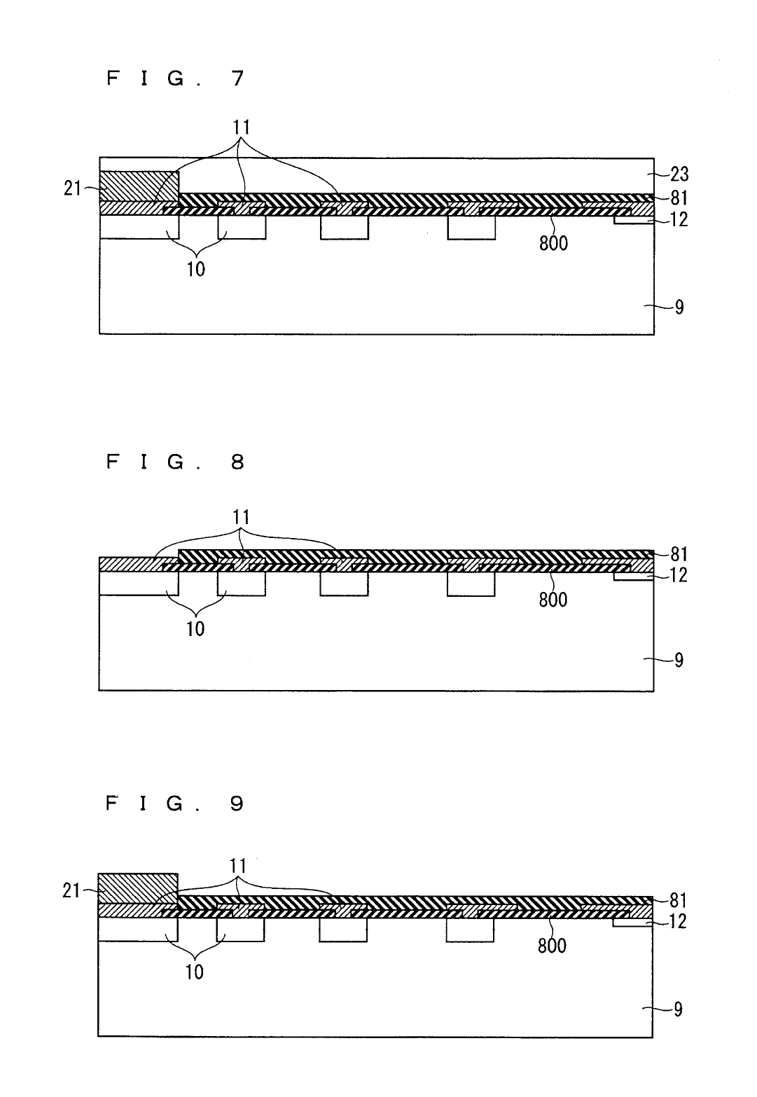

FIG. 7 is a cross-sectional view taken along H-H′ of FIG. 2. As shown in FIG. 7, the p well layers 10 are formed in the surface of the n− substrate 9, and in the termination region 1, a plurality of ring-shaped p well layers 10, which surround the region in which the first emitter electrode 2 is formed in plan view, are formed. Further, the channel stopper 12 is formed on the outermost boundary. While a plurality of p well layers 10 are formed in a ring shape in FIG. 7, one p well layer 10 may be formed in a ring shape.

The first field plate electrodes 11 connected to the upper surfaces of the respective p well layers 10 and the channel stopper 12, which are not covered with the interlayer insulating film 800, are formed on the respective p well layers 10 and the channel stopper 12. The first field plate electrodes 11 are formed so as to surround the cell region in which a plurality of cells are formed in plan view.

Further, the first field plate electrodes 11 are covered with the interlayer insulating film 81 as a third interlayer insulating film, while the first field plate electrode 11 that is not covered with the interlayer insulating film 81 is left, and the second field plate electrode 21 connected to the first field plate electrode 11 is formed on the left first field plate electrode 11.

As shown in FIG. 7, it is desirable that the second field plate electrode 21 have a thickness larger than the thickness of the first field plate electrode 11.

Further, a protective film 23 can be formed so as to cover the second field plate electrode 21 and the interlayer insulating film 81.

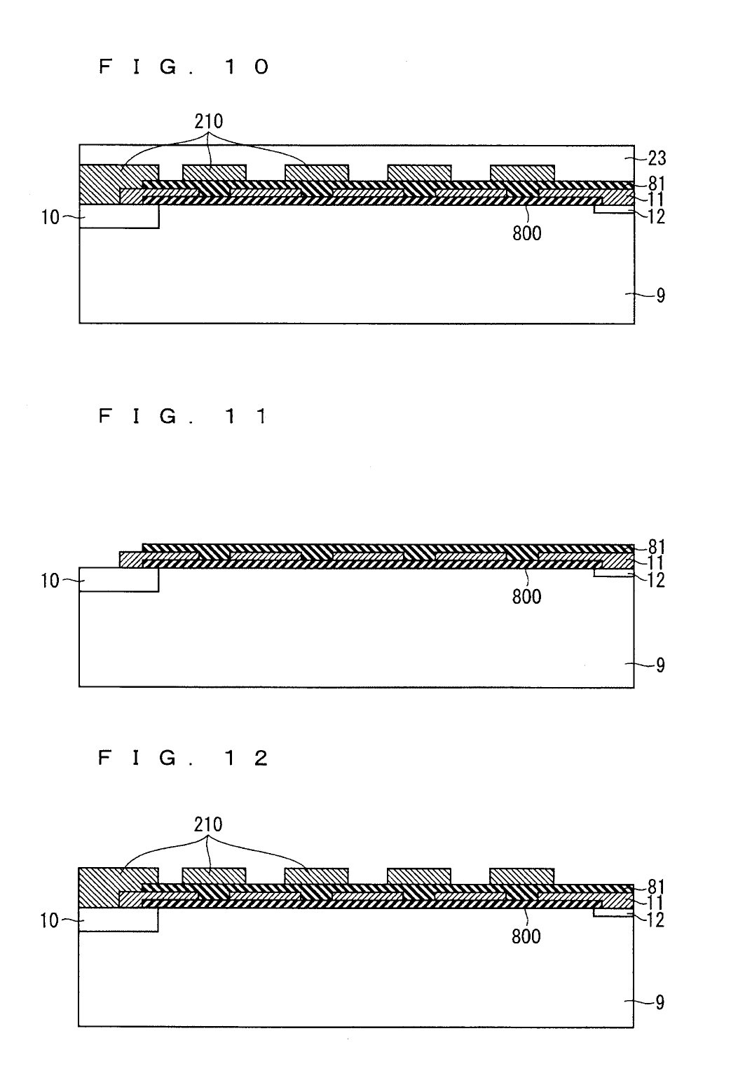

FIGS. 8 and 9 show the method of manufacturing the semiconductor device shown in FIG. 7.

First, the p well layers 10 for selectively extending a depletion layer during voltage application and the channel stopper 12 for stopping the depletion layer on the outermost boundary are formed on the n− substrate 9, and then the interlayer insulating film 800 is formed by the method such as deposition (FIG. 8).

After that, a conductive material such as aluminum is deposited by the method such as sputtering and deposition, and the obtained film is selectively etched to form the first field plate electrode 11 (FIG. 8). Then, the interlayer insulating film 81 is formed by a similar method, and the second field plate electrode 21 is selectively manufactured (FIG. 9).

In this manner, the breakdown voltage can be maintained by the termination structure with the use of the first field plate electrodes 11 and the second field plate electrode 21.

In this case, in the semiconductor device according to the present invention, the first field plate electrode 11, which is the electrode for grounding the potential of the termination region 1, and the second field plate electrode 21, which is the electrode for improving wire bondability, are manufactured in different steps.

In the case of the semiconductor device according to the underlying technology of the present invention, the electrode for grounding the potential of the termination region 1 and a thick Al electrode for improving wire bondability are manufactured at the same time. This causes a problem that in a device embedded in a mold resin, the field plate electrode (Al) having the termination structure peels off (slides) over time due to a difference in rate of thermal expansion of a mold, Si and aluminum. However, in the present invention, the second field plate electrode 21 is formed in another step as described above, which prevents the occurrence of sliding due to slimming down of the second field plate electrode 21 having the termination structure.

In this case, it is possible to form the first gate wiring line 5, the first emitter electrode 2 and the first field plate electrode 11 in the same step.

Further, the second gate wiring line 16, the second emitter electrode 15 and the second field plate electrode 21 can be formed in the same step.

In such a case, the number of steps is reduced, leading to effects such as a cost reduction and efficiency improvement.

Further, the semi-insulating protective film 23 of silicon nitride or the like for protection from water, stress, impurities and the like is formed on the other second field plate electrode 21 (FIG. 7). This leads to the effects that the breakdown voltage is stabilized and that the electrode is prevented from becoming deformed due to the stress of a mold.

<C-2. Configuration 2>

FIG. 10 shows a modified example of the cross section taken along H-H′ of FIG. 2. As shown in FIG. 10, the p well layer 10 is formed in the surface of the n− substrate 9. Further, the channel stopper 12 is formed on the outermost boundary.

The first field plate electrode 11 connected to the upper surfaces of the p well layer 10 and the channel stopper 12, which are not covered with the interlayer insulating film 800, are formed on the respective p well layers 10 and the channel stopper 12, and in the region in which the p well layer 10 is formed to the region in which the channel stopper 12 is formed, a plurality of first field plate electrodes 11 are formed on the interlayer insulating film 800.

The first field plate electrodes 11 are covered with the interlayer insulating film 81, and further, a plurality of third field plate electrodes 210 are formed. The third field plate electrode 210 has, for example, a ring shape to surround the cell region. In addition, the third field plate electrode 210 is formed so as to partially overlap the first field plate electrodes 11 in plan view. The formation described above stabilizes the breakdown voltage of the semiconductor device.

Further, the protective film 23 is formed so as to cover the third field plate electrodes 210 and the interlayer insulating film 81.

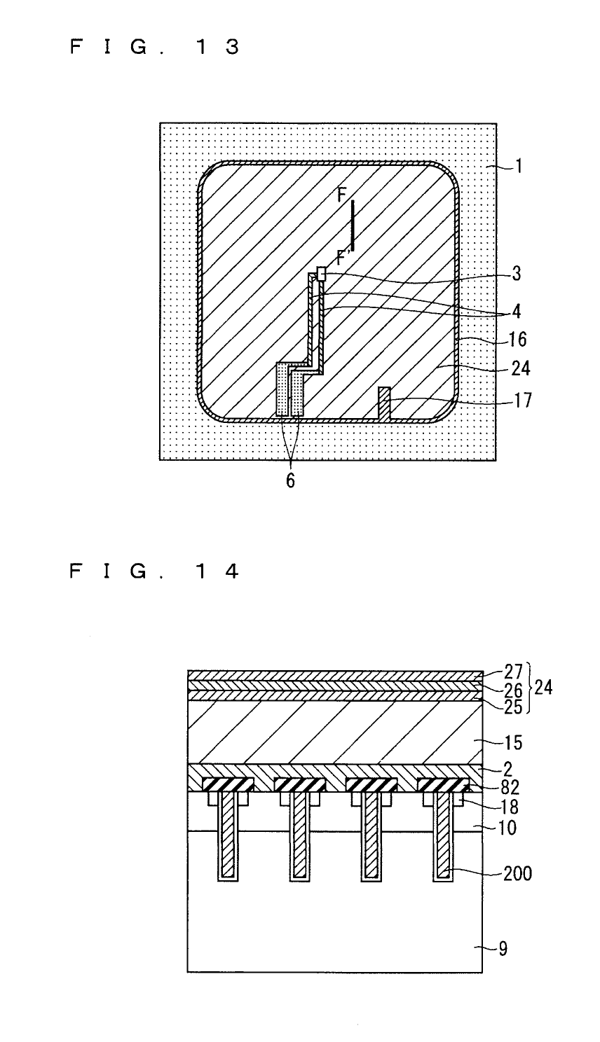

FIGS. 11 and 12 show the method of manufacturing the semiconductor device shown in FIG. 10.

First, the p well layer 10 for selectively extending the depletion layer during voltage application and the channel stopper 12 for stopping the depletion layer on the outermost boundary are formed in the surface of the n− substrate 9, and then the interlayer insulating film 800 is formed by the method such as deposition.

After that, a conductive material such as aluminum is deposited by the method such as sputtering and deposition, and the obtained film is selectively etched, thereby forming the first field plate electrodes 11 (FIG. 11). Then, the interlayer insulating film 81 is formed by a similar method, and the third field plate electrodes 210 are selectively formed, whereby capacitive coupling is achieved (FIG. 12).

Note that the second gate wiring line 16, the second emitter electrode 15 and the second field plate electrode 210 can be formed in the same step.

In the case of the semiconductor device according to the present invention shown in FIG. 19, the first field plate electrode 11 is made of polysilicon which forms the gate electrode 20, which imposes limitations on manufacturing. On the other hand, in this preferred embodiment, the first field plate electrode 11 and the second field plate electrode 21 can be manufactured by the first emitter electrode 2 and the second emitter electrode 15, respectively. Accordingly, the termination structure can be manufactured without any limitations on manufacturing.

<C-3. Effects>

According to the third preferred embodiment of the present invention, the semiconductor device further includes: the first field plate electrode 11 surrounding the cell region including the plurality of cells formed therein in plan view; the interlayer insulating film 81 as a third interlayer insulating film, which covers a region other than part of the upper surface of the first field plate electrode 11; and the second field plate electrode 21 connected to the first field plate electrode 11 through part of the upper surface that is not covered with the interlayer insulating film 81. Accordingly, the breakdown voltage of the semiconductor device can be stabilized.

Further, according to the third preferred embodiment of the present invention, in the semiconductor device, the thickness of the second field plate electrode 21 is larger than the thickness of the first field plate electrode 11. Accordingly, it is possible to prevent the generation of sliding due to slimming down of the second field plate electrode 21 having the termination structure.

Further, according to the third preferred embodiment of the present invention, the semiconductor device further includes the third field plate electrode 210 formed on the interlayer insulating film 81 serving as the third interlayer insulating film and surrounding the cell region in plan view, the third field plate electrode 210 partially overlapping the first field plate electrode 11 in plan view. Accordingly, the breakdown voltage of the semiconductor device can be stabilized.

Further, according to the third preferred embodiment of the present invention, the semiconductor device further includes the protective film 23 formed on the interlayer insulating film 81 serving as the third interlayer insulating film. Accordingly, the breakdown voltage of the semiconductor device can be stabilized. In addition, the electrode can be prevented from becoming deformed by the stress of a mold.

### D. Fourth Preferred Embodiment

<D-1. Configuration>

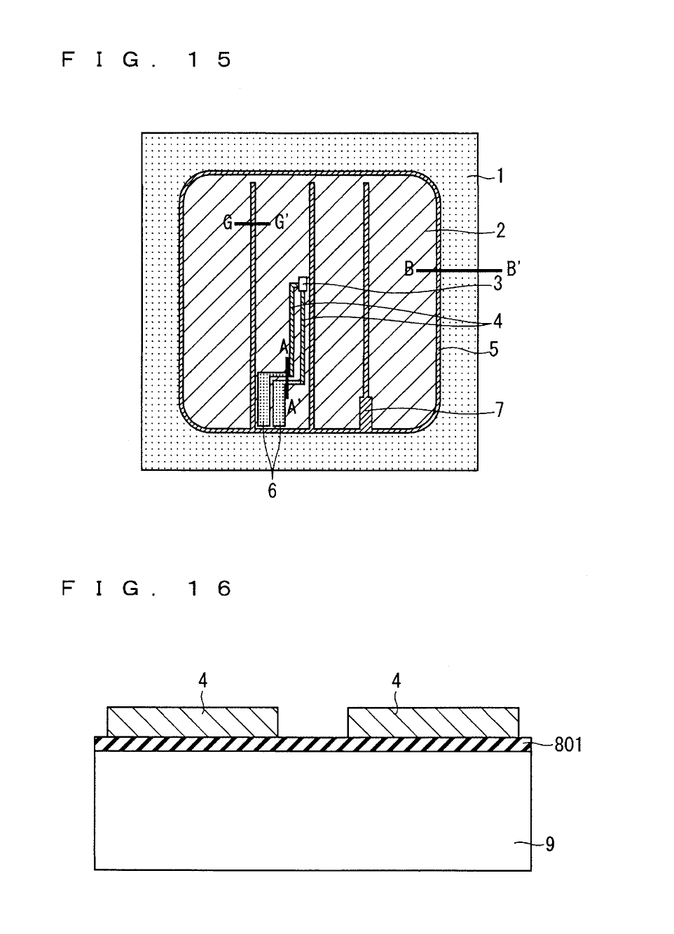

FIG. 13 shows an upper main surface of a semiconductor device according to a fourth preferred embodiment of the present invention. In plan view, the cell region in which a third emitter electrode 24 is formed is surrounded by the second gate wiring line 16, and the region outside the cell region is the termination region 1.

In the region in which the third emitter electrode 24 is formed, the temperature sensing diode 3 is disposed in the center part thereof, and the wiring lines 4 for the temperature sensing diode 3, which are connected to the temperature sensing diode 3, and further the electrode pads 6 for the temperature sensing diode 3, which are connected to the wiring lines 4, are disposed.

FIG. 14 is a cross-sectional view taken along F-F′ of FIG. 13. As shown in FIG. 14, the p well layer 10 (p base layer) is formed on the n− substrate 9, and the individual gate electrodes 200 are formed so as to extend from the surface of the p well layer 10 (p base layer) to the inside of the n− substrate 9.

Further, the n+ emitter layers 18 are formed to sandwich the individual gate electrodes 200 in the surface of the p well layer 10. Moreover, the interlayer insulating film 82 is formed in the surface of the p well layer 10 so as to cover the individual gate electrodes 200.

Further, the first emitter electrode 2 is formed so as to cover the p well layer 10 including the interlayer insulating film 82. A MOS transistor is formed below the first emitter electrode 2.

The second emitter electrode 15 is formed on the first emitter electrode 2, and further, a third emitter electrode 24 that can be solder-bonded is formed thereon.

An electrode including three layers can be used as the third emitter electrode 24 and, for example, the electrode may include a third emitter electrode 25 (Ti), a third emitter electrode 26 (Ni) and a third emitter electrode 27 (Au). The respective electrodes are deposited by the method such as sputtering and deposition, and are selectively etched.

Soldering on the electrode of the chip surface reduces the on-resistance upon energization and obtains a longer period of time before the bonding surface with the chip peels off compared with wire bonding. Generally, the gate wiring line on the chip surface inhibits the flexibility in soldering. In the fourth preferred embodiment, the second emitter electrode 15 covers the first gate wiring line 5 through the interlayer insulating film 8, which increases the flexibility in soldering.

As described above, this preferred embodiment achieves the effects that the flexibility in soldering is increased, that the on-resistance upon energization is reduced, and that the electrode is prevented from becoming deformed by the stress of the mold of a package.

<D-2. Effects>

According to the fourth preferred embodiment of the present invention, the semiconductor device further includes the third emitter electrode 24 formed on the second emitter electrode 15 and being bondable by soldering. Accordingly, the breakdown voltage of the semiconductor device is stabilized. In addition, the electrode can be prevented from becoming deformed by the stress of a mold.

Further, according to the fourth preferred embodiment of the present invention, in the semiconductor device, the third emitter electrode 25, 26, 27 includes an electrode of Ti/Ni/Au. Accordingly, the breakdown voltage of the semiconductor device is stabilized further. In addition, it is possible to prevent the electrode from becoming deformed by the stress of a mold.

While the materials of the respective components, the conditions of implementation and the like are described in the preferred embodiments of the present invention, the foregoing description is in all aspects illustrative and not restrictive.

What is claimed is:

1. A semiconductor device, comprising:
a gate electrode selectively located on an insulating film and connected to individual gate electrodes of a plurality of cells;
a first interlayer insulating film located on said insulating film so as to cover a region other than part of an upper surface of said gate electrode;
a first gate wiring line connected to said gate electrode through said upper surface that is not covered with said first interlayer insulating film;
a second interlayer insulating film located on said first interlayer insulating film so as to cover a region other than part of an upper surface of said first gate wiring line; and
a second gate wiring line connected to said first gate wiring line through said upper surface of said first gate wiring line that is not covered with said second interlayer insulating film, said second gate wiring line having a width larger than a width of said first gate wiring line in plan view.

2. The semiconductor device according to claim 1, further comprising:
a first field plate electrode surrounding a cell region including said plurality of cells located therein in plan view;
a third interlayer insulating film covering a region other than part of an upper surface of said first field plate electrode; and
a second field plate electrode connected to said first field plate electrode through part of said upper surface that is not covered with said third interlayer insulating film.

3. The semiconductor device according to claim 2, wherein a thickness of said second field plate electrode is larger than a thickness of said first field plate electrode.

4. The semiconductor device according to claim 2, further comprising a third field plate electrode located on said third interlayer insulating film and surrounding said cell region in plan view, said third field plate electrode partially overlapping said first field plate electrode in plan view.

5. The semiconductor device according to claim 2, further comprising a protective film located on said third interlayer insulating film.

6. The semiconductor device according to claim 1, further comprising:
emitter layers for the respective cells, said emitter layers being located adjacent to said individual gate electrodes;
a fourth interlayer insulating film located so as to cover said individual gate electrodes;
a first emitter electrode located on said fourth interlayer insulating film so as to be connected to said emitter layers;
a fifth interlayer insulating film located on said first emitter electrode; and
an electrode pad for a temperature sensing diode and/or a wiring line for said temperature sensing diode, which are/is located on said fifth interlayer insulating film.

7. The semiconductor device according to claim 6, further comprising a second emitter electrode located on said first emitter electrode.

8. The semiconductor device according to claim 7, wherein:
said second interlayer insulating film is located so as to cover said first gate wiring line at least partially; and
said second emitter electrode is located at a position of said partially-covered first gate wiring line so as to cover a region including a portion above said second interlayer insulating film in place of said second gate wiring line.

9. The semiconductor device according to claim 7, further comprising a third emitter electrode located on said second emitter electrode and being bondable by soldering.

10. The semiconductor device according to claim 9, wherein said third emitter electrode comprises Ni.

11. The semiconductor device according to claim 9, wherein said third emitter electrode includes an electrode of Ti/Ni/Au.

12. A method of manufacturing a semiconductor device, the semiconductor device comprising:
a gate electrode selectively located on an insulating film and connected to individual gate electrodes of a plurality of cells;
a first interlayer insulating film located on said insulating film so as to cover a region other than part of an upper surface of said gate electrode;
a first gate wiring line connected to said gate electrode through said upper surface that is not covered with said first interlayer insulating film;
a second interlayer insulating film located on said first interlayer insulating film so as to cover a region other than part of an upper surface of said first gate wiring line;
a second gate wiring line connected to said first gate wiring line through said upper surface that is not covered with said second interlayer insulating film, said second gate wiring line having a width larger than a width of said first gate wiring line in plan view;
emitter layers for the respective cells, said emitter layers being located adjacent to said individual gate electrodes;
a fourth interlayer insulating film located so as to cover said individual gate electrodes;
a first emitter electrode located on said fourth interlayer insulating film so as to be connected to said emitter layers;
a fifth interlayer insulating film located on said first emitter electrode;
an electrode pad for a temperature sensing diode and/or a wiring line for said temperature sensing diode, which are/is located on said fifth interlayer insulating film; and
a second emitter electrode located on said first emitter electrode,
wherein said electrode pad for said temperature sensing diode and said wiring line for said temperature sensing diode are formed in the step of forming said second gate wiring line and said second emitter electrode.

13. The method of manufacturing a semiconductor device according to claim 12, wherein said first gate wiring line, said first emitter electrode and said first field plate electrode are formed in the same step.

14. The method of manufacturing a semiconductor device according to claim 12, wherein said second gate wiring line, said second emitter electrode and said second field plate electrode are formed in the same step.
